(19) United States
(12) Patent Application Publication
(10) Pub. No.: US 2013/0102131 A1
(43) Pub. Date: Apr. 25, 2013

(54) METHOD OF MANUFACTURING SEMICONDUCTOR DEVICE

(71) Applicants: Hiromu YAMAGUCHI, Tokyo (JP); Satoru SUGIYAMA, Tokyo (JP); Kazuaki TONARI, Tokyo (JP)

(72) Inventors: Hiromu YAMAGUCHI, Tokyo (JP); Satoru SUGIYAMA, Tokyo (JP); Kazuaki TONARI, Tokyo (JP)

(73) Assignee: ELPIDA MEMORY, INC, Tokyo (JP)

(21) Appl. No.: 13/610,032

(22) Filed: Sep. 11, 2012

(30) Foreign Application Priority Data
Oct. 21, 2011 (JP) 2011-231357

(51) Int. Cl. H01L 21/20

(52) U.S. Cl. 438/478; 257/E21.09

(57) ABSTRACT

A method of manufacturing a semiconductor device wherein a film containing Si and Ge is formed on a conducting film over a substrate by using a raw material gas containing Si and a raw material gas containing Ge, includes: forming Si nuclei on the conducting film at a first ratio of a flow rate of the raw material gas containing Ge to a flow rate of the raw material gas containing Si; and forming, on the Si nuclei, a film having Si and Ge at a second ratio of the flow rate of the raw material gas containing Ge to the flow rate of the raw material gas containing Si, the second ratio being greater than the first ratio.

This application is based upon and claims the benefit of priority from Japanese patent application No. 2011-231357, filed on Oct. 21, 2011, the disclosure of which is incorporated herein in its entirety by reference.

### TECHNICAL FIELD

This invention relates to a method of manufacturing a semiconductor device.

### BACKGROUND

The size reduction has been remarkably progressing in the field of DRAMs (Dynamic Random Access Memory). Capacitors used in such DRAMs are formed into a three-dimensional structure in order to ensure a large capacity. This type of capacitor is formed by covering the surface of a lower electrode which is formed three-dimensionally with a capacity insulating film and an upper electrode. In order to form upper and lower electrodes made of titanium nitride (TiN) films, a CVD (Chemical Vapor Deposition) method is required. However, in the CVD method, film formation is performed at a high temperature of 550° C. or more. Therefore, if thick films are formed at such a high temperature, the thermal load applied to the capacity insulating film will become excessively large, possibly leading to deterioration in insulating properties. This makes it necessary to form the upper electrode to have a thickness as small as 10 nm or less. As a result, after formation of the upper electrode, a gap is produced between adjacent capacitors. This gap is filled with a filling film (conductor) which is preferably a boron-doped silicon germanium (B—SiGe) film that can be formed at a low temperature of 500° C. or less.

This type of technique is disclosed, for example, in Japanese Patent Application Publication Nos. 2004-320022 and 2006-339632.

However, according to these techniques, when a filling film (B—SiGe) is formed on the upper electrode (TiN) of a capacitor, the thickness distribution of the filling film is remarkably deteriorated.

### SUMMARY

In one embodiment, there is provided a method of manufacturing a semiconductor device wherein a film containing Si and Ge is formed on a conducting film over a substrate by using a raw material gas containing Si and a raw material gas containing Ge, comprising:

forming Si nuclei on the conducting film at a first ratio of a flow rate of the raw material gas containing Ge to a flow rate of the raw material gas containing Si; and

forming, on the Si nuclei, a film having Si and Ge at a second ratio of the flow rate of the raw material gas containing Ge to the flow rate of the raw material gas containing Si, the second ratio being greater than the first ratio.

In another embodiment, there is provided a method of manufacturing a semiconductor device, comprising:

preparing a semiconductor substrate comprising a conducting film;

setting the semiconductor substrate in a film formation apparatus;

forming Si nuclei on the conducting film by introducing a raw material gas containing Si into the film formation apparatus by opening a valve for the raw material gas containing Si while closing a valve for a raw material gas containing Ge; and

forming a film having Si and Ge on the Si nuclei by introducing the raw material gas containing Ge and the raw material gas containing Si into the film formation apparatus by opening the valve for the for the raw material gas containing Si and the valve for the raw material gas containing Ge.

### BRIEF DESCRIPTION OF THE DRAWINGS

The above features and advantages of the present invention will be more apparent from the following description of certain preferred embodiments taken in conjunction with the accompanying drawings, in which

FIG. 1A is a cross-sectional view of a semiconductor device (DRAM) 100 to which the invention is applied;

FIG. 1B is an enlarged view of a region surrounded by the broken line in FIG. 1A;

FIG. 2 is a cross-sectional view of a principal part of a thin film formation apparatus used for formation of a filling film 18;

FIG. 3 is a flowchart showing manufacturing steps of a semiconductor device according to an exemplary embodiment of the invention;

FIG. 4 is a diagram showing one step of the manufacturing method of the semiconductor device according to the embodiment of the invention;

FIG. 5 is a diagram showing one step of the manufacturing method of the semiconductor device according to the embodiment of the invention;

FIG. 6A is cross-sectional view showing one step of the manufacturing method of the semiconductor device according to the embodiment of the invention;

FIG. 6B is enlarged view of a region surrounded by the broken line in FIG. 6A;

FIG. 7 is a diagram showing one step of the manufacturing method of the semiconductor device according to the embodiment of the invention;

FIG. 8 is a diagram showing one step of the manufacturing method of the semiconductor device according to the embodiment of the invention;

FIG. 9 is a diagram showing one step of the manufacturing method of the semiconductor device according to the embodiment of the invention;

FIGS. 10A to 10E are diagrams schematically showing in time series respective states of formation of a filling film 18 according to the embodiment of the invention;

FIGS. 11A to 11D are diagrams schematically showing in time series respective states of formation of a filling film 18 according to a conventional technique;

FIG. 12A is a schematic plan view of the state shown in FIG. 10C;

FIG. 12B is a schematic plan view of the state shown in FIG. 11C;

FIG. 13 is a graph showing a correlation between average thickness and uniformity of thickness of the filling film 18 in the plane of a semiconductor substrate and positions of semiconductor substrates 30 in a wafer boat 31; and

FIG. 14 is a correlation diagram between concentration of chlorine (Cl) contained in the upper electrode 16 and stress of a formed boron-doped SiGe film.

### DESCRIPTION OF EXEMPLARY EMBODIMENTS

The present invention will be now described herein with reference to illustrative exemplary embodiments. Those skilled in the art will recognize that many alternative embodiments can be accomplished using the teachings of the present invention and that the invention is not limited to the exemplary embodiments illustrated for explanatory purposes.

Exemplary embodiments of the invention will be described in detail with reference to the drawings.

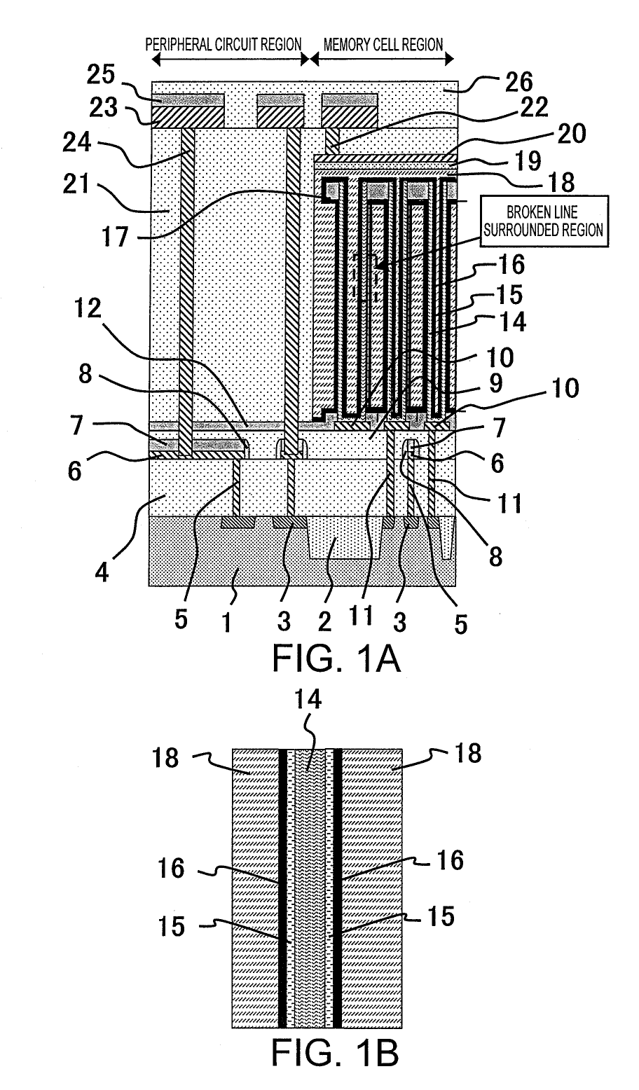

Referring to FIGS. 1A and 1B, description will be made in terms of an example in which a semiconductor device 100 to which the invention is applied is a DRAM (Dynamic Random Access Memory). FIG. 1A is a cross-sectional view of the semiconductor device 100, and FIG. 1B is an enlarged view of the region surrounded by the broken line in FIG. 1A.

A semiconductor substrate 1 has an element isolation region 2 made of an insulating film, and impurity diffusion regions 3 in which impurity ions are diffused. There are stacked, on the semiconductor substrate 1, a gate insulating film made of a thermal oxidation film, a gate electrode and an etching mask, and the side faces thereof are covered with a side-wall insulating film, whereby a transistor (not shown) is formed.

An interlayer insulating film 4 having the transistor buried therein is provided with contact plugs 5 which are connected the impurity diffusion regions 3. Bit lines 6 are arranged on the interlayer insulating film 4, and connected to the impurity diffusion regions 3 via the contact plugs 5. A mask film 7 is formed on the bit lines 6, and the side faces thereof are covered with a side-wall insulating film 8. The mask film 7 and the side-wall insulating film are buried in an interlayer insulating film 9. Capacity contact pads 10 are arranged on the interlayer insulating film 9, and connected to the impurity diffusion regions 3 via the contact plugs 11. Further, a stopper film 12 and an interlayer insulating film 21 are stacked to cover the interlayer insulating film 9.

A lower electrode 14, a capacity insulating film 15 and an upper electrode 16 are provided in the interlayer insulating film 21 in a memory cell region to form a capacitor. As shown in FIG. 1B, the capacity insulating film 15 and the upper electrode 16 are formed on each side face of the lower electrode 14. A support film 17 is connected to the top end of the lower electrode 14. The lower electrode 14 having a U-shape is covered with a filling film 18 via the capacity insulating film 15 and the upper electrode 16 formed on the surfaces thereof. A plate electrode 20 is provided on the filling film 18 via an adhesive layer 19.

In the memory cell region, a contact plug 22 is provided in the interlayer insulating film 21 covering the plate electrode 20 and is connected to the plate electrode 20. Likewise, in a peripheral circuit region, contact plugs 24 are provided in the interlayer insulating film 21 and are connected to the bit lines 6. Wirings 23 are provided on the interlayer insulating film 21. In the memory cell region, the wiring 23 is connected to the contact plugs 22, while in the peripheral circuit region, the wirings 23 are connected to the contact plugs 24. The wirings 23 are buried in an interlayer insulating film 26 via a mask film 25 formed on the wrings 23.

As described above, a capacitor composed of the lower electrode 14, the capacity insulating film 15 and the upper electrode 16 is connected to a transistor in the memory cell region of the semiconductor device (DRAM) 100, so that the capacitor is charged and discharged by turning ON/OFF the transistor.

In the semiconductor device (DRAM) 100, an amount of charge stored in the capacitor is used as memory information. Therefore, a certain amount or more of charge is required in order to ensure stable operation. In such a memory cell, the size of the capacitor has also been reduced as a result of the size reduction of the memory cell, the thickness of the capacity insulating film 15 is reduced in order to ensure a certain amount or more of charge. However, when the thickness of the capacity insulating film 15 is reduced, the strength of the capacity insulating film 15 will become poor, which will induce film stress. The film stress will increase leak current of the capacitor. Therefore, in order to reduce the film stress of the capacity insulating film 15, the filling film 18 is required to have a uniform thickness. An embodiment of the invention relates to a method of forming the filling film 1 in the semiconductor device (DRAM) 100.

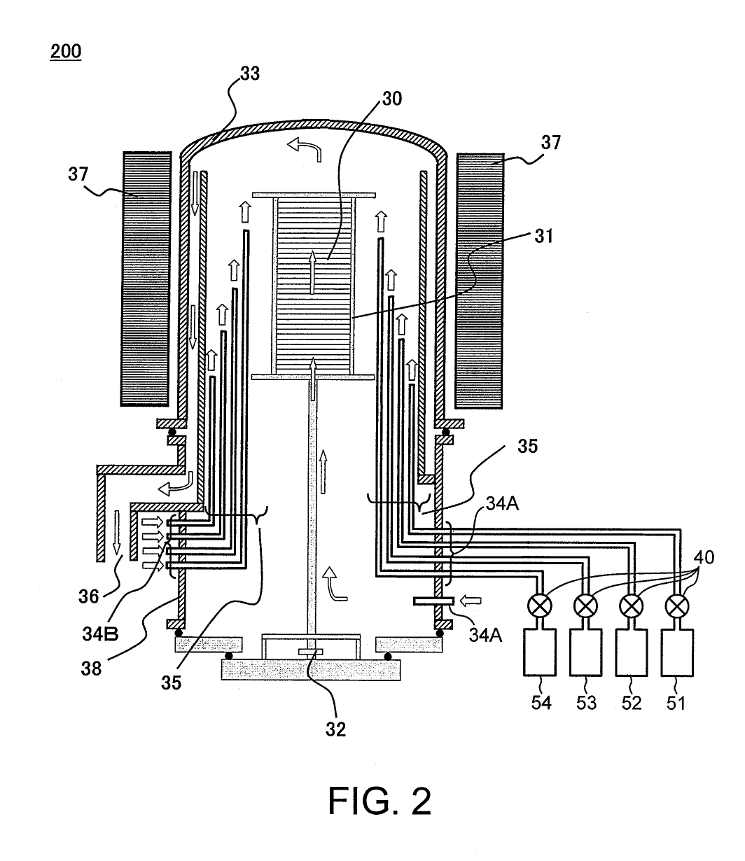

Next, a film formation apparatus to be used for forming the filling film 18 will be described with reference to FIG. 2. FIG. 2 is a cross-sectional view showing a principal part of the film formation apparatus 200.

As shown in FIG. 2, the thin film formation apparatus 200 has a housing 38, in which arranged are a wafer boat 31 on which semiconductor substrates 30 are placed stationary, a drive unit 32 for rotating the wafer boat 31, a tube 33 serving as a film formation chamber, a gas supply port 34 and a gas introduction pipe 35 for supplying a raw material gas to the semiconductor substrates 30 within the film formation chamber 33, an exhaust port 36 for discharging the raw material gas from the film formation chamber 33, and a heater 37 for heating the film formation chamber 33.

The gas supply port 34 is composed of a gas supply port 34A for supplying a raw material gas to the film formation chamber 33 through the inside of the housing 38, and a gas supply port 34B connected to the gas introduction pipe 35 for supplying the raw material gas directly to the film formation chamber 33. The gas introduction pipe 35 is arranged upright in a gap between the side face of the tube 33 and the wafer boat 31. The raw material gas is ejected from the front end of the gas introduction pipe 3, flows between the adjacent semiconductor substrates 30, and eventually moves to the exhaust port 36 where a negative pressure is established. Three different raw material gases are used for formation of the filling film 18, and each raw material gas is supplied from a gas supply port 34 selected according to its mixing specification. Further, a system is designed such that required amounts of raw material gases are supplied from the respective raw material gas supply sources 51 to 54 into the film formation chamber 33, at their timings of use, by controlling valves 40 provided in the respective gas supply ports 34.

In this example, the raw material gas supply sources 51 is a Si raw material gas supply source, the raw material gas supply sources 52 is a Ge raw material gas supply source, the raw material gas supply source 53 is a B raw material gas supply source, and the raw material gas supply source 54 is a raw material gas supply source selected as necessary.

The raw material gas is caused to chemically react by heating the raw material gas and the semiconductor substrates 30 by means of the heater 37 disposed outside of the film formation chamber 33 to produce a product of reaction, and the filling film 18 is formed on the semiconductor substrate 30 by this product of reaction.

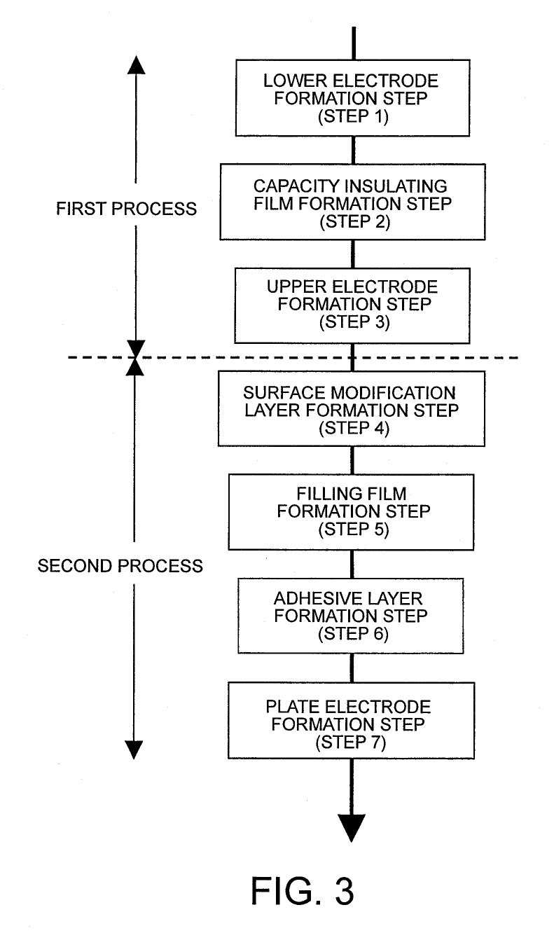

Referring to FIG. 3, a manufacturing method of the semiconductor device (DRAM) 100 according to this embodiment will be schematically described. FIG. 3 shows a process flow to manufacture a capacitor according to this embodiment. In the following description, the components of the semiconductor device (DRAM) 100 are assigned with the safe reference numerals as in FIG. 1.

The process flow of FIG. 3 consists of two principal processes, namely a first process and a second process. The first process is for forming principal components of the capacitor, namely a lower electrode 14, a capacity insulating film 15, and an upper electrode 16, and the second process is for forming a plate electrode 20.

In the first process, firstly, a lower electrode 14 is formed in an interlayer insulating film 13 to be described later (step 1).

Next, the inner surface and outer side faces of the lower electrode 14 are exposed, and then a capacity insulating film 15 is formed to cover the lower electrode 14 (step 2).

Finally, an upper electrode 16 is formed to cover the capacity insulating film 15 (step 3).

In the second process, a surface modification layer of molecular nuclei consisting of Si and H is formed on the surface of the upper electrode 16 by adhering a first decomposition product (SiH₂) produced by thermally decomposing monosilane (SiH₄) as the raw material gas (step 4).

Next, a filling film 18 is formed so as to fill the gap between adjacent upper electrodes 16 (step 5).

Finally, an adhesive layer 19 for preventing the peel-off of a plate electrode 20 is formed on the filling film 18 (step 6), and then the plate electrode 20 is formed on the adhesive layer 19 (step 7).

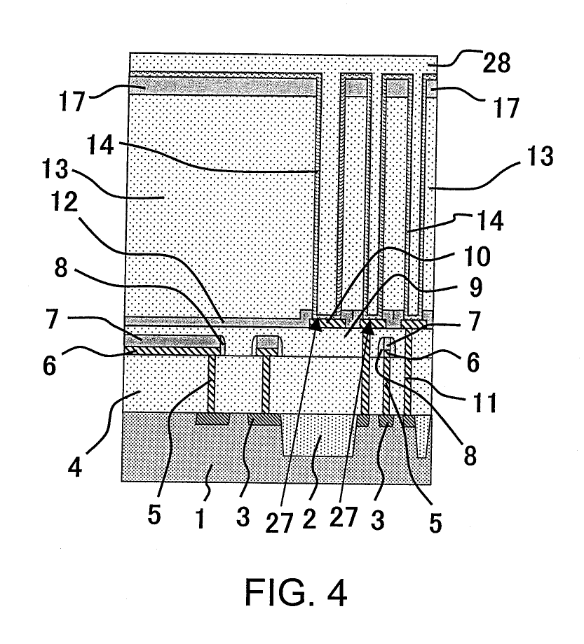

Next, referring to FIGS. 4 to 9, the manufacturing method shown in FIG. 3 will be described in detail.

(Preparation Step)

Referring to FIG. 4, an element isolation trench is formed in the semiconductor substrate 1 by using a photolithography technique and a dry etching technique.

Subsequently, an element isolation region 2 is formed by filling the element isolation trench with a silicon nitride (SiN) film or a silicon oxide (SiO₂) film by means of a CVD (Chemical Vapor Deposition) method.

A gate insulating film which is a silicon oxide film formed by a thermal oxidation method, a polysilicon (Si) layer formed by a LPCVD (Low Pressure CVD) method and a tungsten (W) layer formed by a sputtering method are stacked on the semiconductor substrate 1. The stacked structure is then patterned by using a photolithography technique and a dry etching technique to form a word line (not shown) having a polymetal structure composed of polysilicon and tungsten.

Next, an impurity diffusion region 3 is formed in the region of the semiconductor substrate 1 not covered with the word line, by means of a photolithography technique and an ion implantation method.

As a result of the foregoing processing, a planar MOS transistor is formed, composed of the gate insulating film, the word line as a gate electrode and the impurity diffusion region 3 as a source/drain.

Next, an interlayer insulating film 4 made of a silicon oxide film is formed by a CVD method so as to bury the semiconductor elements, and then contact holes are formed in the interlayer insulating film 4 by a photolithography technique and a dry etching technique.

Subsequently, the contact holes are filled with tungsten by a CVD method, and then the tungsten located on the interlayer insulating film 4 is removed by CMP (Chemical Mechanical Polishing) to form contact plugs 5.

Next, tungsten and silicon nitride films are stacked by a CVD method, and the stacked films are patterned by a photolithography technique and a dry etching technique to form bit lines 6 made of tungsten.

A silicon nitride film is formed by a CVD method so as to cover the bit lines 6 and then etched back to form side-wall insulating films 8 covering the side faces of the bit lines 6.

Subsequently, an interlayer insulating film 9 made of a silicon oxide film is formed by a CVD method so as to bury the bit lines 6, and then the surface of the interlayer insulating film 9 is flattened by CMP.

A tungsten film is formed on the interlayer insulating film 9 by a CVD method, and then patterned by using a photolithography technique and a dry etching technique so that capacity contact pads 10 are formed.

Subsequently a silicon nitride film is formed by a CVD method so as to cover the capacity contact pads 10, whereby a stopper film 12 is formed.

The first process in the process flow shown in FIG. 3 will be described in detail below.

(Lower Electrode Formation Step: step 1 in FIG. 3)

An interlayer insulating film 13 made of a silicon oxide film and a support film 17 made of a silicon nitride film are stacked on the stopper film 12 by a CVD method.

Subsequently, by using a photolithography technique and a dry etching technique, cylinder holes 27 are formed to pass through the support film 17, the interlayer insulating film 13 and the stopper film 12. Thus, the top faces of the capacity contact pads 10 are exposed in the bottoms of the cylinder holes 27.

Next, a titanium nitride (TiN) film to be lower electrodes is formed by a SFD (Sequential Flow Deposition) method so as to cover the inner surfaces of the cylinder holes 27. The thickness of this titanium nitride film is a half or less of the inner diameter of the cylinder holes 27, and thus the cylinder holes 27 are not completely filled with the titanium nitride film and are partially left as holes.

Next, a cover film 28 made of a silicon oxide film is formed by the CVD method so as to fill the cylinder holes 27, whereby a structure as shown in FIG. 4 is obtained.

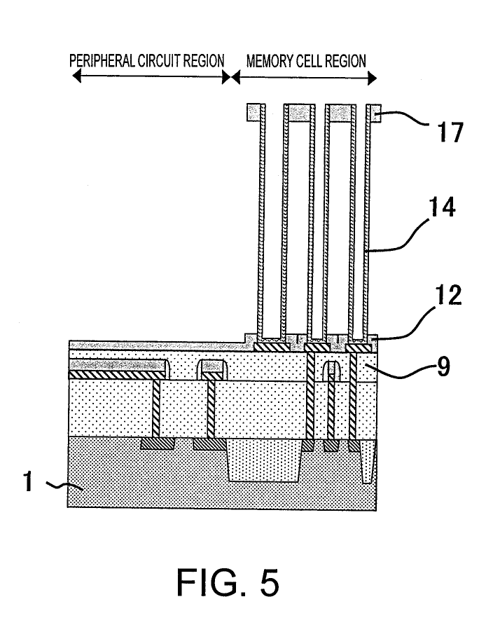

Referring to FIG. 5, the support film 17 in the peripheral circuit region is removed by the photolithography technique and the dry etching technique, so that the top face of the interlayer insulating film 13 in the peripheral circuit region is exposed. During this process, lower electrode 14 can be formed simultaneously by adjusting the thickness of a photoresist film so that the cover film and the titanium nitride on the support film 17 in the memory cell region can be removed at the same time with completion of removal of the support film 17 in the peripheral circuit region.

Next, the interlayer insulating film 13 made of a silicon oxide film and the cover film 28 buried in the cylinder holes are completely removed by a wet etching technique using hydrofluoric acid (HF). In this etching process, the interlayer insulating film 9 covered with the stopper film 12, the lower electrode 14 and the support film 17 are left unremoved. This is because the silicon nitride films forming the stopper film 12 and support film 17 and the titanium nitride forming the lower electrode 14 are not removed by hydrofluoric acid. The adjacent lower electrode 14 are connected to each other by means of the support film 17 left unremoved, and hence are allowed to stand upright without collapsing. The inner surfaces and outer side surfaces of the lower electrode 14 are exposed by removing the interlayer insulating film 13.

(Capacity Insulating Film Formation Step: step 2 in FIG. 3)

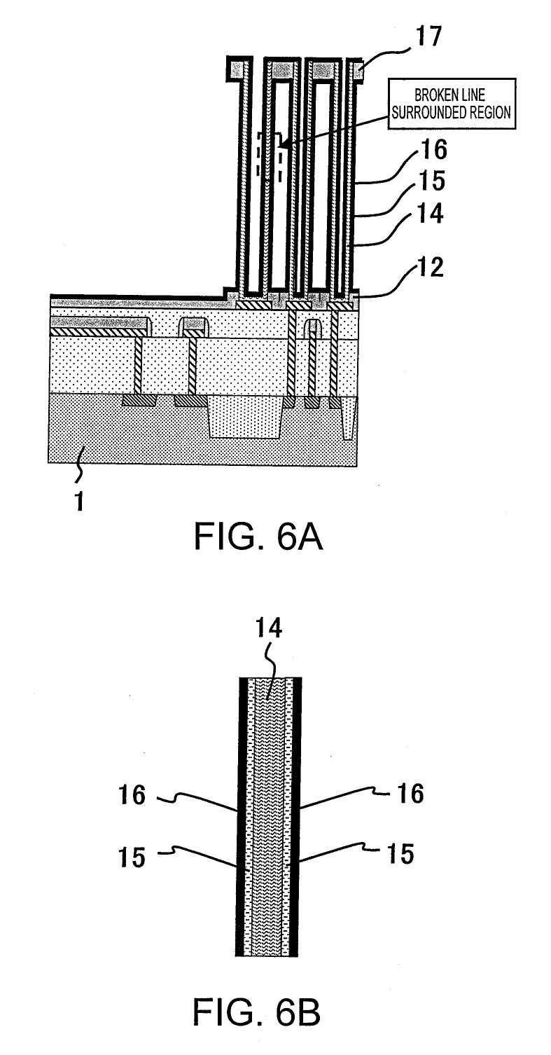

As shown in FIGS. 6A and 6B, a capacity insulating film 15, which is a thin film formed by alternately stacking aluminum oxide (Al₂O₃) and zirconium oxide (ZrO) by an ALD (Atomic Layer Deposition) method, is formed so as to cover the surfaces of the lower electrode 14.

(Upper Electrode Formation Step: step 3 in FIG. 3)

Next, upper electrodes 16 made of titanium nitride are formed by a SFD method so as to cover the surface of the capacity insulating film 15. As seen from FIG. 6B showing the region surrounded by the broken line in an enlarged scale, the capacity insulating film 15 and the upper electrode 16 uniformly cover the side faces of the lower electrode 14. Further, the surfaces of the support film 17 and the stopper film 12 are also covered with the capacity insulating film 15 and the upper electrode 16. The SFD method is a method to efficiently form a highly precise thin film by supplying two or more different process gases in each film formation step. In the formation of the lower electrode 14 and the upper electrode 16, a step of simultaneously supplying titanium tetrachloride (TiCl₄) and ammonia (NH₃) as the process gases and a step of supplying only ammonia are repeated alternately, so that titanium nitride is formed.

Other than the SFD method, it is also possible to use a conventional CVD method to form titanium nitride, in which titanium tetrachloride (TiCl₄) and ammonia (NH₃) are supplied simultaneously. Both of these methods require a temperature of 550° C. or more for the film formation. This high temperature does not pose a problem when forming the lower electrode 14. When forming the upper electrode 16, however, the capacity insulating film 15 has already been formed, and if the upper electrode 16 is formed to a thickness of 10 nm or more, the duration of heat treatment for the formation of the upper electrode itself at a temperature of 550° C. or more becomes so long as to induce a problem of deterioration of the insulating properties of the capacity insulating film 15.

Therefore, the upper electrode 16 must be formed to a thickness of 10 nm or less. In this case, at the stage of formation shown in FIG. 6(a), the spaces in the inside of the lower electrodes 14 and the spaces between the adjacent lower electrodes cannot be filled sufficiently with the upper electrode 16 and the spaces are partially left unfilled even after formation of the upper electrode 16. Such spaces left unfilled will cause deterioration of mechanical strength, and stress generated due to a subsequent film formation or packaging process will be applied to the capacitor, possibly resulting in deformation of the capacitor.

The deformation of the capacitor means deformation of the capacity insulating film 15, which will induce deterioration of properties, leading to increased leak current. Therefore, the aforementioned spaces must be filled completely. According to this embodiment, a conductor that can be formed at a low temperature, namely a boron-doped SiGe film is used to fill the spaces.

A second process in the process flow shown in FIG. 3 will be described below.

Since a boron-doped SiGe film can be formed at a temperature of 500° C. or less, the formation of the boron-doped SiGe film does not induce a problem of deterioration of insulating properties of the capacity insulating film 15. However, as a result of experiments, the inventors of this invention have found that there occurs a problem when a boron-doped SiGe film is formed on a TiN film that is formed as the upper electrode 16, that the film thickness distribution becomes large within the surface of a substrate or among a plurality of substrates formed at the same time.

When the film thickness distribution becomes large, there occurs a problem in a processing step to be described later, that the capacitor will be exposed in a part of the boron-doped SiGe film having a smaller thickness, while taking more time to etch a part of the boron-doped SiGe film having a larger thickness. This makes it impossible to form a capacitor having normal characteristics. The inventors have found, as a result of various studies conducted in order to reduce the thickness distribution of a boron-doped SiGe film formed on a TiN film, that it is effective to form a Si—H absorption layer made of molecular Si and H as a surface modification layer on the surface of the TiN film prior to formation of the boron-doped SiGe film.

(Surface Modification Layer Formation Step: step 4 in FIG. 3)

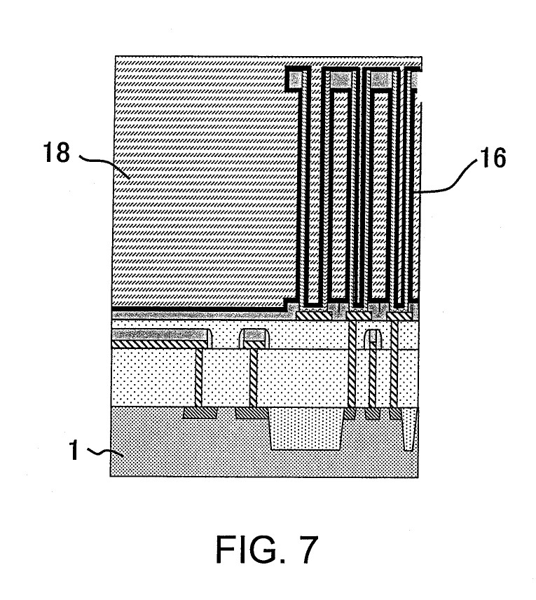

Referring to FIG. 7, molecules of silicon (Si) and hydrogen (H) are adsorbed on the surface of TiN forming the upper electrode 16 by using a thermal decomposition method of monosilane (SiH₄). The thin film formation apparatus 200 shown in FIG. 2 can be used to perform this process. One hundred substrates 30 with a diameter of 300 mm and having the upper electrode 16 formed thereon are set in the film formation chamber 33.

After the film formation chamber 33 is once evacuated, nitrogen (N₂) is introduced into the film formation chamber 33 through the gas supply ports 34A, 34B and stabilized at a temperature of 450° C. and a pressure of 40 Pa. Subsequently, monosilane (SiH₄) as the raw material gas is introduced into the film formation chamber 33 through the gas supply port 34B for a period of 500 to 700 seconds. The monosilane (SiH₄) is thereby thermally decomposed to become a first decomposition product (SiH₂) in active state, a part of which is physically adsorbed on the surface of the TiN forming the upper electrode 16 by Van der Waals force, whereby a surface modification layer is formed.

The first decomposition product (SiH₂) is physically adsorbed at substantially uniform intervals. This is because when the silicon (Si) in the first decomposition product (SiH₂) is physically adsorbed on the upper electrode 16, hydrogen (H) molecules bonded to the silicon (Si) repel each other, whereby the intervals between the silicon (Si) molecules are naturally uniformized. Although, in this example, nitrogen (N₂) is once introduced after the evacuation, and monosilane (SiH₄) is finally introduced, it is also possible to introduce monosilane (SiH₄) directly after the evacuation, omitting the introduction of nitrogen (N₂). In this case, it takes shorter time to replace the air within the film formation chamber 33 with monosilane (SiH₄), and hence the supply time of the monosilane (SiH₄) can be shortened to a range of 200 to 400 seconds. Further, disilane (Si₂H₆) may be used in place of monosilane. In this case, two molecules of the first decomposition product (SiH₂) can be obtained from one molecule of disilane (Si₂H₆), resulting in improvement of thermal decomposition efficiency. Thus, the density of production of the first decomposition product (SiH₂) can be improved, whereby the supply time of the raw material gas can be shortened furthermore.

In order to form a surface modification layer, it is preferable to cause a gas made of Si to flow more than a gas made of Ge, and it is more preferable not to supply the gas made of Ge in this process. This makes it possible to form the first decomposition product that is molecular nuclei consisting of Si and H.

When the film formation temperature within the chamber 33 is reduced to 400° C., the adhesion density of the first decomposition product is further improved, and thus the first decomposition product can be physically adsorbed more uniformly.

In this exemplary embodiment, the temperature is set to 450° C. and therefore the surface modification layer can be formed more rapidly than when the temperature is set to 400° C. However, if the temperature is 450° C. or less, only one surface modification layer having Si—H molecules as nuclei can be formed on the surface of the upper electrode made of TiN, and no Si film can be formed thereon.

(Filling Film Formation Step: step 5 in FIG. 3)

As shown in FIG. 7, a filling film 18 made of silicon germanium (SiGe) doped with boron (B) is formed, by a LPCVD method, on the upper electrode 16 having the surface modification layer physically adsorbed thereon.

The formation of the filling film 18 is preferably performed continuously following the formation of the surface modification layer, by using the thin film formation apparatus 200 shown in FIG. 2. The conditions for this process are follows. The raw material gas consisting of monosilane (SiH₄), boron trichloride (BCl₃), and monogermane (GeH₄) is supplied at respective flow rates of 787 sccm (standard cubic centimeter per minute) for SiH₄, 3.15 sccm for BCl₃, and 73.5 sccm for GeH₄, while the heating temperature is set to 450° C. and the pressure is set to 40 Pa. The monosilane (SiH₄) and the boron trichloride (BCl₃) are introduced through the gas supply port 34B while the monogermane (GeH₄) is introduced through the gas supply port 34A after mixing the monosilane (SiH₄) and the boron trichloride (BCl₃).

Boron-doped SiGe assumes a polycrystalline state and becomes a conductor having conductivity immediately after formation thereof even if it is formed at a low temperature of 450° C. Boron-doped Si containing no Ge, which is formed at a temperature of 450° C. or less, usually assumes an amorphous state and has no conductivity. However, once Ge is added, the boron-doped Si is formed in a polycrystalline state and becomes a boron-doped SiGe film having conductivity. It can be estimated that this is because Ge itself is a very active substance and has a unique property that it is easy to crystallize even at a low temperature. Boron-doped SiGe is preferably formed at a temperature of 450° C. or more but 500° C. or less.

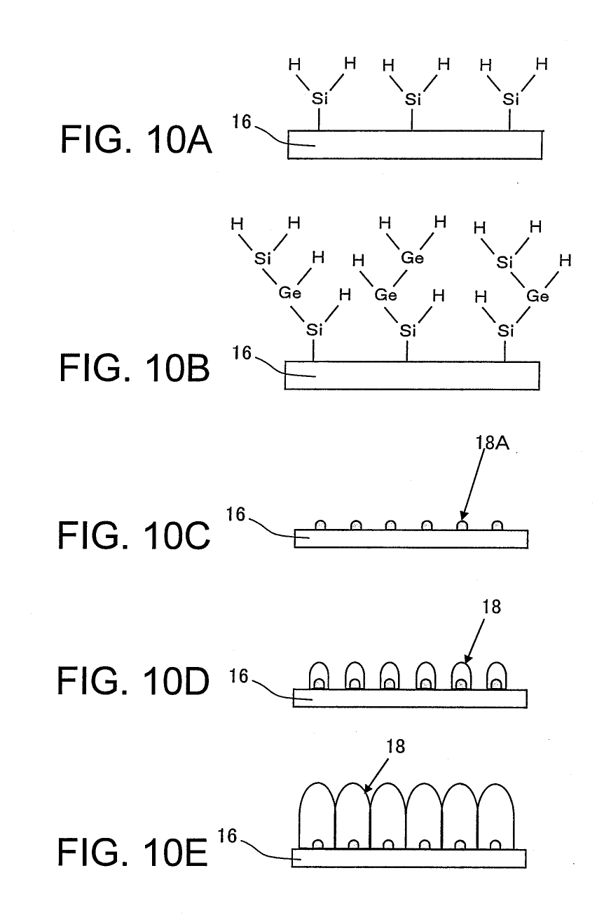

Referring to FIGS. 10A to 10E, the formation process of the filling film 18 will be described. FIGS. 10A to 10E are diagrams schematically showing in time series states of formation of the filling film 18 according to the exemplary embodiment of the invention.

FIG. 10A shows a state in which a surface modification layer 18A made of Si—H molecules is formed on the surface of TiN as the upper electrode 16.

FIG. 10B shows an early stage of growth of the filling film 18 in which hydrogen (H) forming the surface modification layer is substituted with a second decomposition product (GeH₂) that is produced by thermal decomposition of monogermane (GeH₄) as a raw material gas. A boron-doped SiGe film, which is a Si—Ge—B ternary system film, is very difficult to show its full picture with a two-dimensional molecule bond diagram. In FIG. 10B, therefore, the boron-doped SiGe film is shown in the form of an extremely simplified structure principally composed of Si and Ge. Although boron (B) is not shown in this drawing, boron is actually disposed at the positions of Si or Ge to form a P-type conductor.

FIG. 10C is an image of FIG. 10A. In FIG. 10C, the reference numeral 18A indicates Si—H molecular nuclei forming the surface modification layer

FIG. 10D shows a state in which the growth of the filling film 18 has progressed more by repeating, using the nuclei 18A as starting points, substitution reactions with the first decomposition product (SiH₂) and the second decomposition product (GeH₂) produced by thermal decomposition of the raw material gas.

FIG. 10E shows a state in which the filling film 18 made of a boron-doped SiGe film has progressed more and becomes a planarly continuous film. The nuclei 18A, that is, the Si—H molecular nuclei forming the surface modification layer are formed uniformly, and hence the filling film 18 also can be formed uniformly.

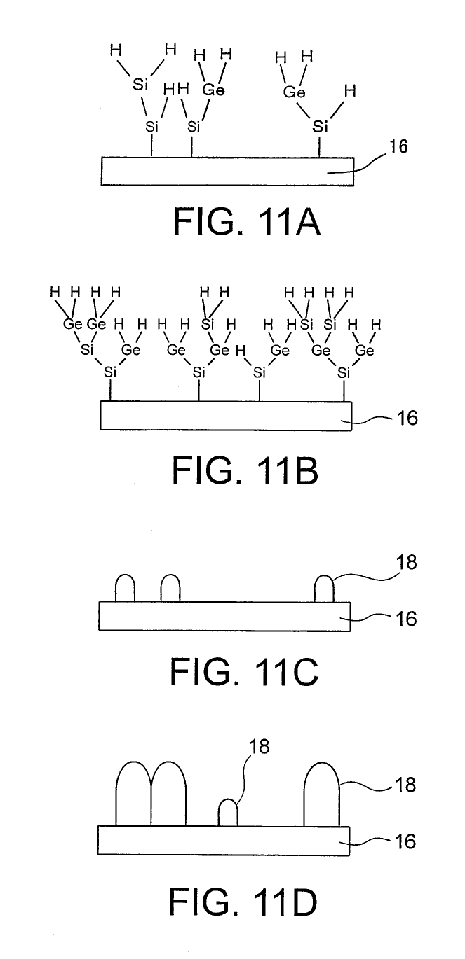

FIGS. 11A to 11D are diagrams schematically showing in time series states of formation of a filling film 18 according to a conventional technique.

According to this conventional technique, a Ge product (GeH₂) is formed on the upper electrode 16 by substituting H of a Si product (SiH₂) (see FIG. 11A).

A SiGe layer is formed by H being further substituted with Si and Ge (see FIG. 11B).

A SiGe layer 18 in an early stage is formed randomly with lapse of time (see FIG. 11C). Therefore, a part of the layer where the reaction occurs earlier is formed to have a greater thickness, while a part where the reaction occurs later is formed to have a smaller thickness, resulting in variation in the thickness of the SiGe layer 18 thus formed (see FIG. 11D).

Thus, Ge is not formed on the upper electrode 16, whereas SiGe is formed by being substituted with H in Si—H. When SiGe is tried to be formed without the Si surface modification layer, the SiGe will grow more rapidly in a part of the upper electrode 16 where Si is formed earlier before formation of Ge, whereas SiGe will grow more slowly in a part where Si is formed later before formation of Ge, resulting in variation in the film thickness.

According to this invention, only Si nuclei are formed uniformly at a low temperature at which only the nuclei are formed (if the temperature is too high, a Si film with poor coverage will be obtained), and then a SiGe layer is formed, using these nuclei as starting points.

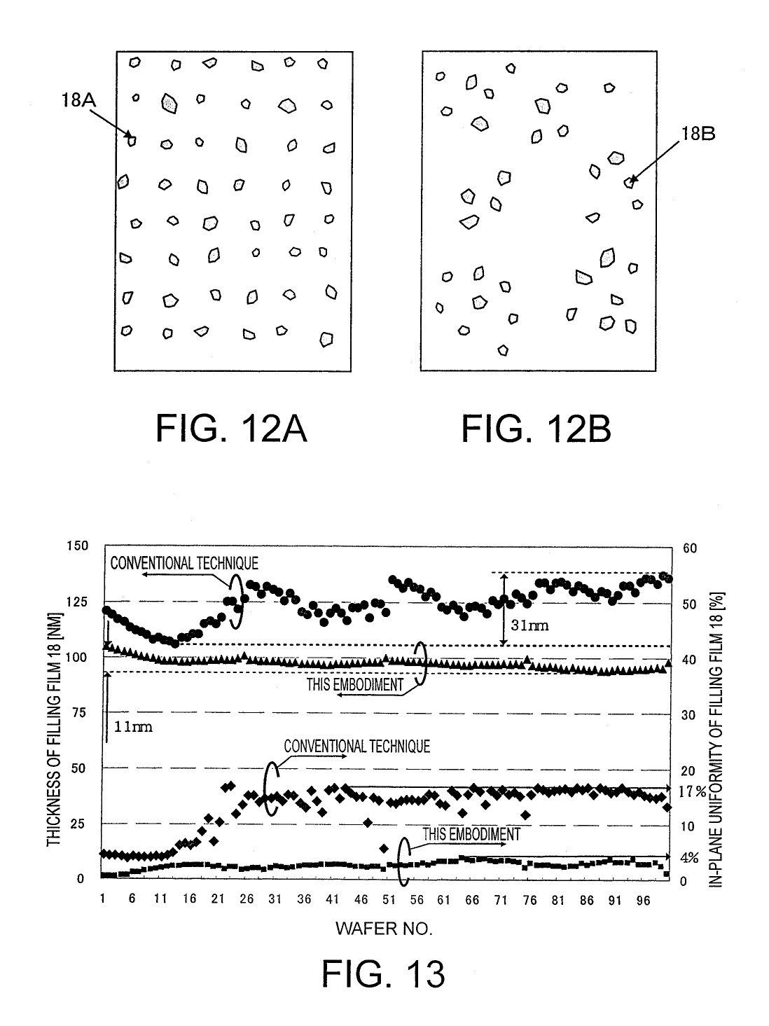

Referring to FIGS. 12A and 12B, states of formation of the SiGe film will be described. FIG. 12A is a schematic diagram showing the state of FIG. 10D as viewed in plan, and FIG. 12B is a schematic diagram showing the state of FIG. 11C as viewed in plan.

The SiGe films 18A in FIG. 10C are formed substantially at regular intervals as shown in FIG. 12A, whereas the SiGe films in FIG. 11C are formed at irregular positions as shown in FIG. 12B.

FIG. 13 shows data obtained by the inventors of this invention, indicating a correlation between average thickness and uniformity of thickness of the filling film 18 in the plane of a semiconductor substrate and positions of semiconductor substrates 30 in the wafer boat 31.

In this example, the lower end of the wafer boat 31 corresponds to the semiconductor substrate No. 1, while the upper end corresponds to the semiconductor substrate No. 100. In the conventional technique, variation in average thickness of semiconductor substrates is 31 nm and the maximum value of in-plane uniformity is 17%, whereas in this embodiment, variation in average thickness of semiconductor substrates is reduced to 11 nm and the maximum value of in-plane uniformity is reduced to 4%. Thus, it is confirmed that the variation in film thickness of the filling film 18 can be reduced by formation of the surface modification layer according to this embodiment.

When forming the boron-doped SiGe film, a BCl₃ film is used as a part of the raw material gas. Therefore, chlorine is introduced as an impurity into the formed film.

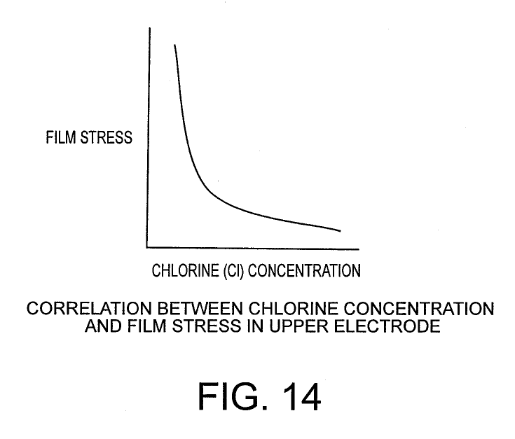

FIG. 14 is a correlation diagram between concentration of chlorine (Cl) contained in the upper electrode 16 and stress of a formed boron-doped SiGe film.

The film stress is in inverse proportion to the concentration of chlorine, and as mentioned before, the leak current of the capacitor is reduced as the film stress becomes lower. The inventors of this invention have confirmed by SIMS (Secondary Ion Mass Spectrometry) that, according to this embodiment, the content of chlorine (Cl) in the upper electrode 16 increases up to 1.7 times more than the Cl content according to the conventional technique. Therefore, according to the embodiment, the film stress can be reduced further and the leak current can be reduced further.

When the upper electrode 16 is completely buried in the filling film 18 formed as described above, the structure shown in FIG. 7 can be obtained. The capacitor is thus completely buried in the filling film 18, while the top face of the filling film 18 is formed as a flat surface above the top face of the capacitor.

(Adhesive Layer Formation Step: step 6 in FIG. 3)

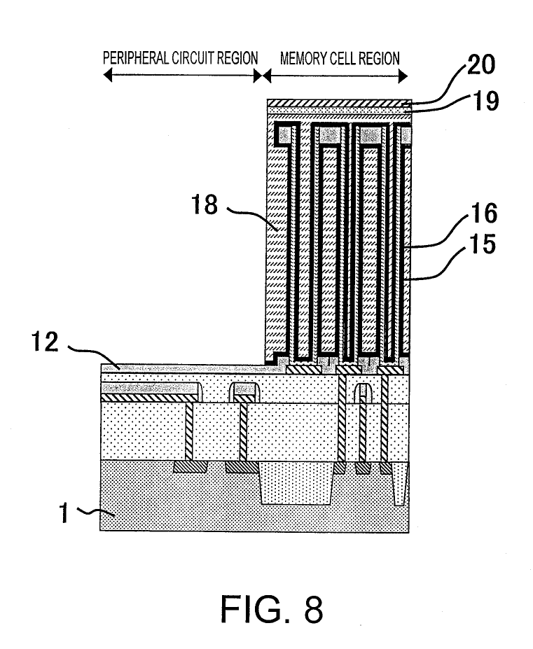

In the next step, as shown in FIG. 8, an adhesive layer 19 made of polysilicon (Si) doped with boron (B) is formed on the filling film 18 by a LPCVD method. After forming the filling film 18, a tungsten (W) film with low resistance is formed on the entire of the memory cell region. If the W film is formed directly on the boron-doped SiGe film, a problem of peeling of the W film may occur.

In this exemplary embodiment, a boron-doped Si film is formed as an adhesive layer in order to avoid this peeling problem. The formation of the boron-doped Si film is preferably performed continuously following the formation of the boron-doped SiGe film, with use of the thin film formation apparatus 200 shown in FIG. 2. This formation is performed under process conditions as follows. The raw material gas consisting of monosilane (SiH₄), boron trichloride (BCl₃), and monogermane (GeH₄) is supplied at respective flow rates of 787 sccm (standard cubic centimeter per minute) for SiH₄, 3.15 sccm for BCl₃, and 73.5 sccm for GeH₄ while the heating temperature is set to 450° C. and the pressure is set to 40 Pa. The monosilane (SiH₄) and the boron trichloride (BCl₃) are introduced through the gas supply port 34B while the monogermane (GeH₄) is introduced through the gas supply port 34A after mixing the monosilane (SiH₄) and the boron trichloride (BCl₃).

Subsequently a plate electrode 20 made of tungsten is formed by a sputtering method so as to cover the surface of the adhesive layer 19. Then, unnecessary films in the peripheral circuit region are removed by using a photolithography technique and a dry etching technique. The unnecessary films in this case are the plate electrode 20, the adhesive layer 19, the filling film 18, and the upper electrode 16. As a result of removal of these unnecessary films, the surface of the stopper film 12 in the peripheral circuit region and the side face of the filling film 18 in the memory cell region are exposed. It is desirable in this dry etching to select a proper etching gas for each of the unnecessary films. Further, the dry etching of the capacity insulating film 15 should desirably be performed under such process conditions that the selective ratio with the stopper film 12 becomes higher in order to facilitate determination of the end point of etching.

As described above, when formed at a temperature of 450° C., the adhesive layer 19 made of boron-doped Si is usually formed (for example, formed on a silicon oxide film) in an amorphous state and has no conductivity. However, as in this embodiment, when the adhesive layer 19 is formed on a boron-doped SiGe film which is already in a polycrystalline state, epitaxial growth occurs on this boron-doped SiGe film functioning as seed crystals, whereby the boron-doped Si film is also formed in a polycrystalline state. Thus, the boron-doped Si film already has conductivity upon formation thereof.

A boron-doped Si film is poorer in step coverage than a boron-doped SiGe film, and hence is unable to completely fill the empty space left around the capacitor. Therefore, a boron-doped Si film cannot be used in place of a boron-doped SiGe film. It is desirable that, before formation of the boron-doped Si film, the top face of the filling film 18 that is formed at a higher level than the top face of the capacitor upon formation of the filling film 18 is formed into a flat plane. The poor step coverage poses no problem when the boron-doped Si film is formed on a flat surface.

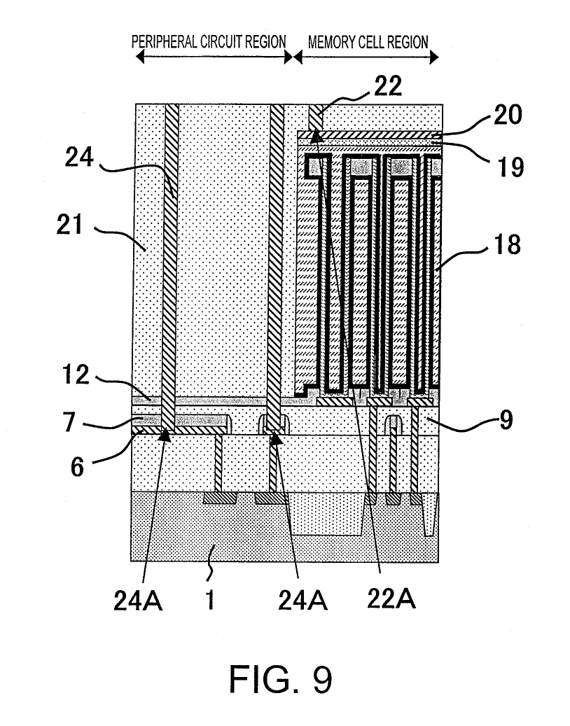

Referring to FIG. 9, an interlayer insulating film 21 made of a silicon oxide film is formed by a CVD method so as to bury the filling film 18, the adhesive layer 19, and the plate electrode 20 in the memory cell region.

Subsequently, the surface of the interlayer insulating film 21 is flattened by CMP (Chemical Mechanical Polishing), and contact holes 22A and 24A are formed by a photolithography technique and a dry etching technique. The contact holes 22A pass through the interlayer insulating film 21 in the memory cell region and the plate electrode 20 is partially exposed in the bottoms of the contact holes 22A. The contact holes 24A pass through the interlayer insulating film 21, the stopper film 12, the interlayer insulating film 9, and the mask film 7 in the peripheral circuit region, and the bit lines 6 are partially exposed in the bottoms thereof.

Next, tungsten is formed by a sputtering method so as to fill the contact holes 22A and 24A, and then the tungsten on the interlayer insulating film 21 is removed by CMP to form the contact plugs 22 and 24. At this point, a structure as shown in FIG. 9 is obtained.

Then, aluminum for forming wirings is formed on the interlayer insulating film 21 by a sputtering method, and then a silicon nitride film for forming a mask film 25 is formed on the aluminum by a CVD method.

The mask film 25 and the aluminum are patterned by a photolithography technique and a dry etching technique to form wirings 23. Further, an interlayer insulating film 26 made of a silicon oxide film is formed by a CVD method so as to bury the wirings 23, and the surface thereof is flattened by CMP. Thus, the semiconductor device (DRAM) 100 as shown in FIG. 1 is obtained.

According to the exemplary embodiment of the invention, when empty spaces produced between adjacent capacitors are filled with B—SiGe, the uniformity in thickness of the B—SiGe film can be improved by performing surface modification by adsorbing a thermal decomposition product (SiH₂) of monosilane (SiH₄) on the surface of TiN for forming an upper electrode.

This means that, according to the exemplary embodiment of the invention, before forming the filling film on the upper electrode, a thermal decomposition product (SiH₂) of monosilane (SiH₄) is uniformly adsorbed on the surface of the upper electrode to form a surface modification layer. Since the filling film is formed starting from the nuclei of a Si—H compound forming the surface modification layer, the thickness of the filling film can be held uniformly. This makes it possible to suppress the non-uniformity in etching during processing of the plate electrodes and to avoid formation of a defective capacitor.

Further, according to the exemplary embodiment of the invention, since BCl₃ is used in a raw material gas for the filling film, chlorine is contained in the filling film. This reduces the film stress of the filling film, whereby the stress applied to the capacity insulating film is alleviated and thus the leak current of the capacitor can be reduced.

Further, according to the exemplary embodiment of the invention, the formation of the surface modification layer, the formation of the filling film and the formation of the adhesive layer are performed at the same low temperature of 450° C. Therefore, when the upper electrode is formed at a temperature of 550° C., the problem of deterioration in insulating properties of the capacity insulating film can be avoided. In addition, the formation steps are performed continuously in the same apparatus, which is effective to improve the productivity.

Although the invention has been described in its preferred form, the invention is not limited to the embodiment as described above. Various modifications and variations are possible without departing from the scope of the invention and all these modifications and variations should be considered to be within the scope of the invention.

What is claimed is:

1. A method of manufacturing a semiconductor device wherein a film containing Si and Ge is formed on a conducting film over a substrate by using a raw material gas containing Si and a raw material gas containing Ge, comprising:
forming Si nuclei on the conducting film at a first ratio of a flow rate of the raw material gas containing Ge to a flow rate of the raw material gas containing Si; and
forming, on the Si nuclei, a film having Si and Ge at a second ratio of the flow rate of the raw material gas containing Ge to the flow rate of the raw material gas containing Si, the second ratio being greater than the first ratio.

2. The method according to claim 1, wherein the first ratio is equal to zero.

3. The method according to claim 1, wherein the forming of the Si nuclei and the forming of the film having Si and Ge are performed in the same chamber.

4. The method according to claim 1, wherein a temperature for forming the Si nuclei is not higher than a temperature for forming the film having Si and Ge.

5. The method according to claim 4, wherein the Si nuclei is formed at a temperature of 400° C. or more but 450° C. or less.

6. The method according to claim 4, wherein the film having Si and Ge is formed at a temperature of 450° C. or more but 500° C. or less.

7. The method according to claim 1, wherein the Si nuclei is formed by a film which is produced by thermal decomposition of silicon hydride gas.

8. The method according to claim 7, wherein the silicon hydride gas is produced by using monosilane SiH4.

9. The method according to claim 7, wherein the silicon hydride gas is produced by using disilane Si2H6.

10. The method according to claim 1, wherein the Si nuclei is formed by molecular nuclei including silicon bonded with hydrogen.

11. The method according to claim 1, wherein the film having Si and Ge contains boron.

12. The method according to claim 11, wherein the film having Si and Ge further contains chlorine.

13. The method according to claim 11, wherein the film having Si and Ge is formed by using monosilane (SiH4) gas, monogermane (GeH4) gas, and boron trichloride (BCl3) gas.

14. The method according to claim 1, further comprising:
forming an adhesive layer containing boron and silicon on the film having Si and Ge.

15. The method according to claim 14, further comprising:
forming a metal film on the adhesive layer.

16. The method according to claim 15, wherein the conducting film contains titanium nitride while the metal film contains tungsten.

17. A method of manufacturing a semiconductor device, comprising:
preparing a semiconductor substrate comprising a conducting film;
setting the semiconductor substrate in a film formation apparatus;
forming Si nuclei on the conducting film by introducing a raw material gas containing Si into the film formation apparatus by opening a valve for the raw material gas containing Si while closing a valve for a raw material gas containing Ge; and
forming a film having Si and Ge on the Si nuclei by introducing the raw material gas containing Ge and the raw material gas containing Si into the film formation apparatus by opening the valve for the for the raw material gas containing Si and the valve for the raw material gas containing Ge.

18. The method according to claim 17, wherein a temperature for forming the Si nuclei is not higher than a temperature for forming the film having Si and Ge.

19. The method according to claim 18, wherein the Si nuclei is formed at a temperature of 400° C. or more but 450° C. or less.

20. The method according to claim 18, wherein the film having Si and Ge is formed at a temperature of 450° C. or more but 500° C. or less.
